(19) United States
(12) Patent Application Publication
(10) Pub. No.: US 2026/0328877 A1
(43) Pub. Date: Oct. 22, 2026

(54) COOLING DEVICE APPLIED TO MEDICAL IMAGING DEVICE, AND MAGNETIC RESONANCE DEVICE

(71) Applicant: Shanghai United Imaging Healthcare Co., Ltd., Shanghai (CN)

(72) Inventor: Rongxing Zhang, Shanghai (CN)

(21) Appl. No.: 19/650,512

(22) Filed: Apr. 17, 2026

(30) Foreign Application Priority Data
Apr. 17, 2025 (CN) 202510488789.8
Dec. 30, 2025 (CN) 202522825792.2

(51) Int. Cl. G01R 33/38; G01R 33/385; H01F 6/04; H05K 7/20

(52) U.S. Cl. CPC G01R 33/3804; G01R 33/3856; H01F 6/04; H05K 7/20263; H05K 7/20272; H05K 7/20281; H05K 7/20354; H05K 7/20372; H05K 7/20927; H05K 7/20945

(57) ABSTRACT

Disclosed are a cooling device applied to a medical imaging device and a magnetic resonance device. The cooling device is configured to adjust the rotation speed of a water pump by obtaining a cooling demand of a phase-specific cooling-required component, to make the cooling liquid delivered by the water pump cool the phase-specific cooling-required component. The cooling device cooperates with a phase-specific control valve to adjust the opening degree to adjust the flow rate of the delivered cooling liquid.

### CROSS-REFERENCE TO RELATED APPLICATIONS

This application claims priority to the Chinese patent application No. 202510488789.8, filed on Apr. 17, 2025, entitled “COOLING DEVICE AND MAGNETIC RESONANCE DEVICE, APPLIED TO MEDICAL IMAGING DEVICE”, and the Chinese patent application No. 202522825792.2, filed on Dec. 30, 2025, entitled “COOLING DEVICE AND MAGNETIC RESONANCE DEVICE, APPLIED TO MEDICAL IMAGING DEVICE”, the entire contents of which are incorporated herein by reference.

### TECHNICAL FIELD

The present disclosure relates to the field of medical technology, in particular to a cooling device and a magnetic resonance device, applied to a medical imaging device.

### BACKGROUND

Most power components in a medical imaging device generate heat during operation. To ensure normal operation of these power components and avoid discomfort to patients during image scanning caused by such heat, the above power components need to be cooled.

Taking a magnetic resonance device as an example, power components in the magnetic resonance device include a superconducting magnet, a gradient coil, a gradient power amplifier, a radio frequency power amplifier, and the like. When the superconducting magnet needs to be maintained in a superconducting state, the superconducting wire needs to be placed in a low-temperature environment below 10K. To maintain the low temperature of the magnet, a cold head is required for cooling, and a helium compressor is required to supply cooling to the cold head. In addition, components such as the gradient coil, the gradient power amplifier, and the radio frequency power amplifier also generate a large amount of heat during operation. To ensure normal operation of the magnetic resonance device, a cooling device is required to dissipate heat for the above components.

In related technologies, cooling devices have relatively high power consumption.

### SUMMARY

In a first aspect, a cooling device applied to a medical imaging device is provided. The medical imaging device includes at least one phase-specific cooling-required component, and the cooling device includes a controller, a variable frequency water pump, and at least one phase-specific control valve. The controller is connected to the at least one phase-specific cooling-required component. The controller is configured to determine a cooling demand of the phase-specific cooling-required component. The controller generates a control instruction according to the cooling demand of the phase-specific cooling-required component. The variable frequency water pump is connected to the phase-specific cooling-required component through a cooling pipeline to deliver a cooling liquid to the phase-specific cooling-required component. The variable frequency water pump is configured to change a rotation speed in response to the control instruction to adjust a delivery volume of the cooling liquid. The at least one phase-specific control valve is arranged between the variable frequency water pump and the phase-specific cooling-required component. The phase-specific control valve is configured to adjust a flow rate of the cooling liquid delivered to the phase-specific cooling-required component by changing an opening degree.

In an embodiment, the medical imaging device further includes a permanent cooling-required component. The cooling pipeline includes a permanent cooling pipeline and a phase-specific cooling pipeline. The medical imaging device further includes a first water diversion structure disposed on the cooling pipeline. The first water diversion structure includes a first permanent port and a first phase-specific port. The first permanent port and the first phase-specific port are connected to the permanent cooling pipeline and the phase-specific cooling pipeline, respectively. The variable frequency water pump is configured to deliver the cooling liquid to the periphery of the permanent cooling-required component through the permanent cooling pipeline via the first permanent port. The cooling liquid delivered by the variable frequency water pump is delivered to the periphery of the phase-specific cooling-required component through the phase-specific cooling pipeline via the first phase-specific port.

In an embodiment, the permanent cooling-required component is a helium compressor. The phase-specific cooling-required component includes a gradient coil, a gradient power amplifier, and a radio frequency power amplifier. The phase-specific cooling pipeline includes three first phase-specific branches. The first water diversion structure includes three first phase-specific ports. The three first phase-specific ports are connected to the three first phase-specific branches in a one-to-one correspondence. The gradient coil, the gradient power amplifier, and the radio frequency power amplifier are connected to the three first phase-specific branches, respectively. A phase-specific control valve is arranged in each of the three first phase-specific branches to independently control the cooling liquid flowing through the three first phase-specific branches.

In an embodiment, the cooling device further includes a heat exchanger and a primary water-cooling assembly. A water inlet of the heat exchanger is connected to the permanent cooling pipeline and the phase-specific cooling pipeline. A water outlet of the heat exchanger is connected to the variable frequency water pump. The primary water-cooling assembly includes a primary water-cooling pump and a primary water-cooling pipeline. The primary water-cooling pipeline is thermally coupled to the heat exchanger. The primary water-cooling pump is configured to drive primary water in the primary water-cooling pipeline. The cooling liquid in the cooling pipeline, driven by the variable frequency water pump, is secondary water.

In an embodiment, the medical imaging device further includes a permanent cooling-required component. The permanent cooling-required component is a helium compressor. The cooling device further includes a primary water-cooling assembly and a heat exchanger. The primary water-cooling assembly includes a primary water-cooling pump and a primary water-cooling pipeline. The primary water-cooling pipeline is connected to the helium compressor. The primary water-cooling pump is configured to drive primary water in the primary water-cooling pipeline. The primary water-cooling pump is configured to deliver the primary water to the helium compressor through the primary water-cooling pipeline. The heat exchanger is thermally coupled to the primary water-cooling pipeline. A water inlet of the heat exchanger is connected to the cooling pipeline. A water outlet of the heat exchanger is connected to the variable frequency water pump. The cooling liquid in the cooling pipeline, driven by the variable frequency water pump, is secondary water. The variable frequency water pump can be turned off when there is no cooling demand of the phase-specific cooling-required component.

A cooling device applied to a medical imaging device is provided. The medical imaging device includes a permanent cooling-required component and at least one phase-specific cooling-required component. The cooling device includes a water pump, a controller, a frequency converter, and at least one phase-specific control valve. The water pump is connected to the permanent cooling-required component and the phase-specific cooling-required component through a cooling pipeline to deliver a cooling liquid to the permanent cooling-required component and the phase-specific cooling-required component. The controller is connected to the at least one phase-specific cooling-required component. The controller is configured to determine a state of the medical imaging device. The controller generates a control instruction corresponding to the state of the medical imaging device. The state of the medical imaging device is determined according to an operating state of the phase-specific cooling-required component. The frequency converter is connected to the controller. The frequency converter is configured to set an operating frequency in response to the control instruction. The operating frequency is related to rotation speed adjustment of the water pump. The at least one phase-specific control valve is arranged between the water pump and the phase-specific cooling-required component. The phase-specific control valve is configured to adjust a flow rate of the cooling liquid delivered to the phase-specific cooling-required component by changing an opening degree.

In an embodiment, the state of the medical imaging device includes one of power-off, hibernation, standby, low-power scanning, and high-power scanning.

In an embodiment, the cooling device includes a plurality of water pumps. One of the water pumps is a first water pump, and the other of the water pumps is a second water pump. The cooling pipeline includes a permanent cooling pipeline and a phase-specific cooling pipeline. The permanent cooling pipeline is connected to the first water pump and the permanent cooling-required component. Thus, at least part of the cooling liquid pumped by the first water pump is used for cooling the permanent cooling-required component. The phase-specific cooling pipeline is connected to the second water pump and the phase-specific cooling-required component. The second water pump is in an off state when the medical imaging device is in a hibernation state or a power-off state.

In an embodiment, the cooling device includes a first temperature detection element configured to obtain a temperature of the phase-specific cooling-required component. The cooling demand of the phase-specific cooling-required component is determined based on temperature information detected by the first temperature detection element.

In an embodiment, the cooling device includes a first water diversion structure connected to the second water pump. The first water diversion structure includes a plurality of first phase-specific ports. The phase-specific cooling pipeline includes a plurality of first phase-specific branches. The plurality of first phase-specific branches are connected to the plurality of first phase-specific ports in a one-to-one correspondence. The plurality of first phase-specific branches are connected to the plurality of phase-specific cooling-required components in a one-to-one correspondence.

In an embodiment, the cooling device includes a first water convergence structure. The first water convergence structure includes a plurality of first water convergence ports. The plurality of first phase-specific branches are connected to the plurality of first water convergence ports in a one-to-one correspondence.

In an embodiment, the cooling device includes a first heat exchanger. A hot water port of the first heat exchanger is connected to the permanent cooling pipeline. A cold water port of the first heat exchanger is connected to the first water pump. The cooling device includes a second heat exchanger. A hot water port of the second heat exchanger is connected to the phase-specific cooling pipeline. A cold water port of the second heat exchanger is connected to the second water pump.

In an embodiment, the cooling device includes a second water diversion structure connected to the first water pump. The second water diversion structure includes a second permanent port and a second phase-specific port. The second permanent port is connected to the permanent cooling pipeline. The second phase-specific port is connected to the cold water port of the second heat exchanger.

In a second aspect, a magnetic resonance device is provided. The magnetic resonance device includes a superconducting magnet, a helium compressor, a first cooling circuit, a power component, and a second cooling circuit. The superconducting magnet is configured to generate a main magnetic field. The helium compressor is configured to cool the superconducting magnet. The first cooling circuit includes a first water pump and a permanent cooling pipeline connected to the first water pump. The first cooling circuit is configured to cool the helium compressor. The power component includes a gradient power amplifier or a radio frequency power amplifier. The second cooling circuit includes a second water pump and a phase-specific cooling pipeline connected to the second water pump. The second cooling circuit is configured to cool the power component. Delivery of the cooling liquid from the second water pump to the gradient power amplifier or the radio frequency power amplifier is stopped when the gradient power amplifier or the radio frequency power amplifier is turned off.

In an embodiment, a phase-specific control valve is arranged on the phase-specific cooling pipeline. The phase-specific control valve is configured to adjust a flow rate of the cooling liquid in the phase-specific cooling pipeline by changing an opening degree of the phase-specific control valve.

In an embodiment, the second water pump is connected to a first water diversion structure. The first water diversion structure includes a plurality of first phase-specific ports. The phase-specific cooling pipeline includes a plurality of first phase-specific branches. The plurality of first phase-specific branches are connected to the plurality of first phase-specific ports in a one-to-one correspondence. The plurality of first phase-specific branches are connected to the plurality of power components in a one-to-one correspondence.

In an embodiment, the magnetic resonance device further includes a first water convergence structure. The first water convergence structure includes a plurality of first water convergence ports. The plurality of first phase-specific branches are connected to the plurality of first water convergence ports in a one-to-one correspondence.

In a third aspect, a magnetic resonance device is provided. The magnetic resonance device includes a superconducting magnet, a helium compressor, a first cooling circuit, a phase-specific cooling-required component, and a second cooling circuit. The superconducting magnet is configured to generate a main magnetic field. The helium compressor is configured to cool the superconducting magnet. The first cooling circuit includes a first water pump, a permanent cooling pipeline, and a first heat exchanger. The first cooling circuit is configured to cool the helium compressor. The phase-specific cooling-required component includes at least one of a gradient power amplifier, a radio frequency power amplifier, and a gradient coil. The second cooling circuit includes a second water pump, a phase-specific cooling pipeline, and a second heat exchanger. The second cooling circuit is configured to cool the phase-specific cooling-required component. The second water pump is in an off state. The first cooling circuit cools the second heat exchanger when the phase-specific cooling-required component is turned off or in a low power consumption state.

In an embodiment, the magnetic resonance device further includes a controller and a frequency converter connected to the controller. The controller is configured to obtain a cooling demand of the phase-specific cooling-required component. The controller controls the frequency converter to adjust an operating frequency of the second water pump according to the cooling demand of the phase-specific cooling-required component.

In an embodiment, a phase-specific control valve connected to the controller is arranged on the phase-specific cooling pipeline. The controller is further configured to control an opening degree of the phase-specific control valve according to the cooling demand of the phase-specific cooling-required component.

### BRIEF DESCRIPTION OF THE DRAWINGS

FIG. 1 is a schematic diagram of a cooling device provided in an embodiment of the present disclosure.

FIG. 2 is a schematic diagram of a cooling device provided in an embodiment of the present disclosure.

FIG. 3 is a schematic diagram of a cooling device provided in an embodiment of the present disclosure.

FIG. 4 is a schematic diagram of a cooling device provided in an embodiment of the present disclosure.

FIG. 5 is a schematic diagram of a cooling device provided in an embodiment of the present disclosure.

FIG. 6 is a schematic diagram of a cooling device provided in an embodiment of the present disclosure.

FIG. 7 is a schematic diagram of a cooling device provided in an embodiment of the present disclosure.

FIG. 8 is a schematic diagram of a cooling device provided in an embodiment of the present disclosure.

FIG. 9 is a schematic diagram of a magnetic resonance device provided in an embodiment of the present disclosure.

FIG. 10 is a schematic diagram of a magnetic resonance device provided in another embodiment of the present disclosure.

### DETAILED DESCRIPTION

To make the above objectives, features, and advantages of the present disclosure more obvious and easier to understand, specific implementations of the present disclosure are described in detail below with reference to the accompanying drawings. Many specific details are set forth in the following description to facilitate a full understanding of the present disclosure. However, the present disclosure can be implemented in many other ways different from those described herein, and those skilled in the art can make similar improvements without departing from the connotation of the present disclosure. Therefore, the present disclosure is not limited by the specific embodiments disclosed below.

In the description of the present disclosure, it should be understood that if terms such as “center”, “longitudinal”, “transverse”, “length”, “width”, “thickness”, “upper”, “lower”, “front”, “rear”, “left”, “right”, “vertical”, “horizontal”, “top”, “bottom”, “inner”, “outer”, “clockwise”, “counterclockwise”, “axial”, “radial”, and “circumferential” appear, the orientations or positional relationships indicated by these terms are based on the orientations or positional relationships shown in the accompanying drawings, which are only for the convenience of describing the present disclosure and simplifying the description, and do not indicate or imply that the referred device or element must have a specific orientation, be constructed and operated in a specific orientation, and thus cannot be construed as limiting the present disclosure.

In addition, when terms such as “first” and “second” appear, these terms are only used for descriptive purposes, and cannot be construed as indicating or implying relative importance or implicitly indicating the number of indicated technical features. Thus, features defined with “first” and “second” may explicitly or implicitly include at least one of such features. In the description of the present disclosure, when the term “a plurality of” appears, the meaning of “a plurality of” is at least two, such as two, three, etc., unless otherwise clearly and specifically defined.

In the present disclosure, unless otherwise clearly specified and limited, when terms such as “install”, “connect”, “couple”, and “fix” appear, these terms should be interpreted in a broad sense. For example, the connection may be a fixed connection, a detachable connection, or an integrated connection; may be a mechanical connection or an electrical connection; may be a direct connection, or an indirect connection through an intermediate medium, or may be internal communication between two elements or an interaction relationship between two elements, unless otherwise clearly limited. For those of ordinary skill in the art, the specific meanings of the above terms in the present disclosure can be understood according to specific circumstances.

In the present disclosure, unless otherwise clearly specified and limited, when a description similar to a first feature being “on” or “under” a second feature appears, it may mean that the first and second features are in direct contact, or the first and second features are in indirect contact through an intermediate medium. Moreover, a first feature being “above”, “over”, and “on” a second feature may mean that the first feature is directly above or obliquely above the second feature, or simply means that the horizontal height of the first feature is higher than that of the second feature. A first feature being “below”, “under”, and “beneath” a second feature may mean that the first feature is directly below or obliquely below the second feature, or simply means that the horizontal height of the first feature is lower than that of the second feature.

It should be noted that when an element is referred to as being “fixed to” or “disposed on” another element, the element may be directly on the other element or there may be an intermediate element therebetween. When an element is referred to as being “connected to” another element, the element may be directly connected to the other element, or there may be an intermediate element therebetween at the same time. When present, terms such as “vertical”, “horizontal”, “upper”, “lower”, “left”, “right”, and similar expressions used herein are for illustrative purposes only and do not represent the only implementation.

Most power components in a medical imaging device generate heat during operation. To ensure normal operation of these power components and avoid discomfort caused by such heat to patients during image scanning, the above power components need to be cooled. Taking the magnetic resonance device as an example, cooling-required components are divided into permanent cooling-required components and phase-specific cooling-required components according to the cooling demands of the power components. A permanent cooling-required component refers to a component that requires cooling at all times, such as a helium compressor. Regardless of whether the magnetic resonance device is in a scanning state, the helium compressor needs to be cooled by a cooling device to maintain the superconducting low-temperature state of the superconducting magnet, otherwise the superconducting magnet will quench and damage the system. Therefore, the helium compressor requires cooling at all times. A phase-specific cooling-required component refers to a component that requires cooling in certain stages, such as scanning, including but not limited to a gradient coil, a gradient power amplifier, a radio frequency transmitting coil, or a radio frequency power amplifier, etc. Cooling of the medical imaging device mainly uses water as a cooling liquid. A pump is configured to drive the cooling liquid to circulate in the cooling pipeline to remove waste heat generated by the operation of each component of the medical imaging device. Generally, the power of the pump is set to enable the cooling liquid to generate the maximum flow required for cooling all components of the medical imaging device, that is, the pump usually keeps operating at the maximum flow power.

In a conventional magnetic resonance device, a cooling device is configured to cool both permanent cooling-required components (i.e., helium compressors) and phase-specific cooling-required components (including gradient coils, gradient power amplifiers, radio frequency transmitting coils, and radio frequency power amplifiers, etc.) at the same time. The cooling device is configured to dissipate heat for the two types of cooling-required components simultaneously and continuously. Due to differences in heat dissipation demands and operation period of different components, unnecessary energy waste is generated, and the power consumption of the cooling device is increased.

Accordingly, an embodiment of the present disclosure provides a cooling device, which can reduce energy loss while adaptively meeting the cooling demands of power components. The cooling device is configured to cool a medical imaging device, and the medical imaging device may include one or more phase-specific cooling-required components 2000. The medical imaging device may be a magnetic resonance (MR) equipment, a positron emission tomography-magnetic resonance (PET-MRI) equipment, a magnetic resonance guided linear accelerator (MR-Linac), etc. A phase-specific cooling-required component may refer to a component that is not always in an operating state, but operates intermittently. For example, when the medical imaging device is in a power-off state, the component does not operate and has no cooling demand. When the medical imaging device is in a standby state, the phase-specific cooling-required component also does not operate and has no cooling demand. When the medical imaging device is in a low-power scanning state, the phase-specific cooling-required component operates but has a low cooling demand. When the medical imaging device is in a high-power scanning state, the component is configured to operate normally and has a high cooling demand.

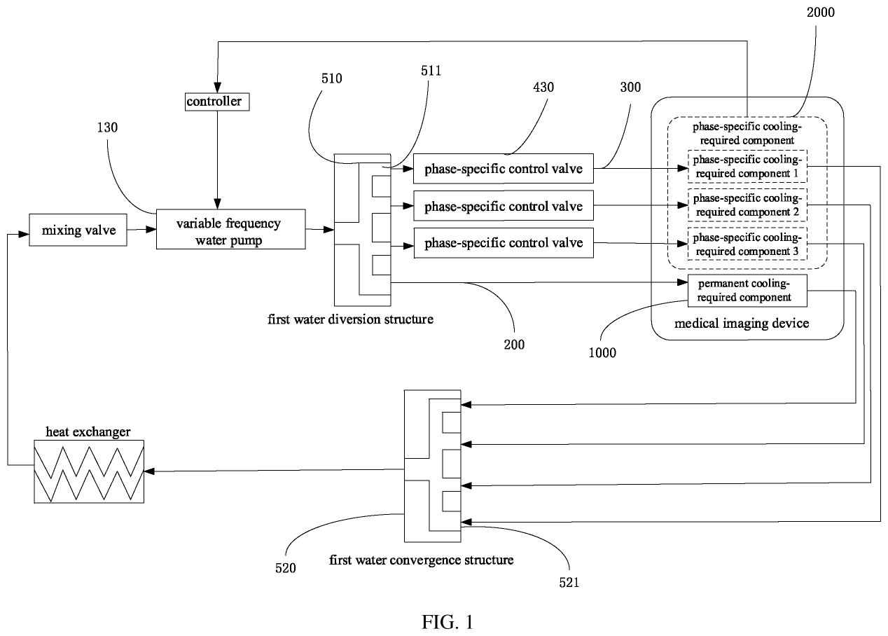

As shown in FIG. 1, the cooling device provided in an embodiment of the present disclosure includes a controller 410, a variable frequency water pump 130, and a phase-specific control valve 430 arranged between the variable frequency water pump 130 and the phase-specific cooling-required component 2000. The controller 410 can be connected to at least one phase-specific cooling-required component 2000, and is configured to determine a cooling demand of the phase-specific cooling-required component 2000, and generate a control instruction according to the cooling demand of the phase-specific cooling-required component 2000. It can be understood that when a plurality of phase-specific cooling-required components 2000 are provided, the controller is connected to all of the plurality of phase-specific cooling-required components 2000. As shown in FIG. 1, arrows connected to the controller indicate information transmission directions. Except for arrows connected to the controller, all other arrows indicate flow directions of the cooling liquid. The connection between the controller 410 and the phase-specific cooling-required component 2000 may be a wired connection, a wireless connection, or a combination of both that enables data interaction and/or data transmission. The wired connection may include a cable, an optical cable, a telephone line, etc., or any combination thereof. The wireless connection may include a Bluetooth network, a Wi-Fi network, a WiMax network, a WLAN, a ZigBee network, a mobile network (e.g., 3G, 4G, 5G, etc.), etc., or any combination thereof. The variable frequency water pump 130 is connected to the phase-specific cooling-required component 2000 through a cooling pipeline to deliver a cooling liquid to the phase-specific cooling-required component 2000. The variable frequency water pump 130 changes its rotation speed in response to the control instruction to adjust the flow rate of the delivered cooling liquid, that is, the variable frequency water pump 130 is configured to change the cooling liquid flow rate thereof and output power in response to the control instruction. The phase-specific control valve 430 adjusts the flow rate of the cooling liquid delivered to the phase-specific cooling-required component by changing an opening degree of the phase-specific control valve 430.

The cooling device is configured to obtain the cooling demand of the phase-specific cooling-required component 2000, and then adjusts the rotation speed of the water pump 100, so that the cooling liquid delivered by the water pump 100 cools the phase-specific cooling-required component 2000. The cooling device cooperates with the phase-specific control valve 430 to adjust the opening degree to adjust the flow rate of the delivered cooling liquid, meeting the actual cooling demand of the phase-specific cooling-required component 2000. For example, when the magnetic resonance device is in the scanning state, the cooling demand of the phase-specific cooling-required component 2000 is relatively high, the rotation speed of the water pump 100 can be increased, correspondingly, the opening degree of the phase-specific control valve 430 increases, and the flow rate of the cooling liquid entering the phase-specific cooling-required component 2000 increases. When the magnetic resonance device is in a standby state, the cooling demand of the phase-specific cooling-required component 2000 is relatively low, the rotation speed of the water pump 100 can be reduced, correspondingly, the opening degree of the phase-specific control valve 430 decreases, and the flow rate of the cooling liquid entering the phase-specific cooling-required component 2000 decreases. When the magnetic resonance device is in a power-off state, the opening degree of the phase-specific control valve 430 is zero. As such, the cooling liquid will not enter the phase-specific cooling-required component 2000. On-demand cooling of the phase-specific cooling components is realized, and the cooling loss of the phase-specific cooling-required component 2000 in non-scanning states, such as a standby state and a power-off state, is reduced, so that the power consumption of the cooling device is reduced.

In some embodiments, the medical imaging device can further include a permanent cooling-required component 1000. The permanent cooling-required component 1000 may refer to a component that is always in the operating state. For example, regardless of whether the medical imaging device is in a power-off state, a standby state, a low-power scanning state, or a high-power scanning state, the permanent cooling-required component 1000 operates continuously, and the cooling demand of the permanent cooling-required component 1000 always exists.

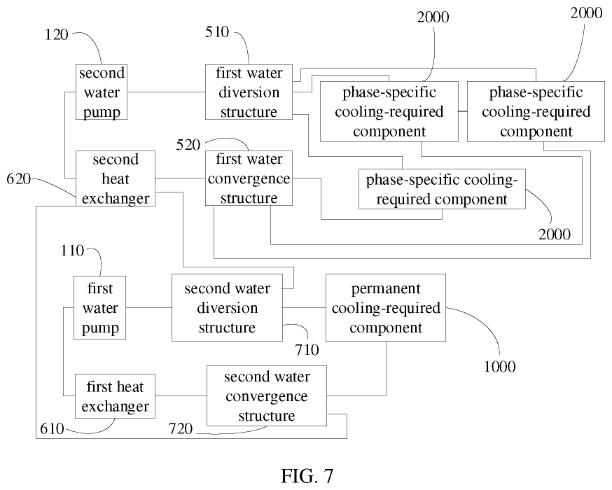

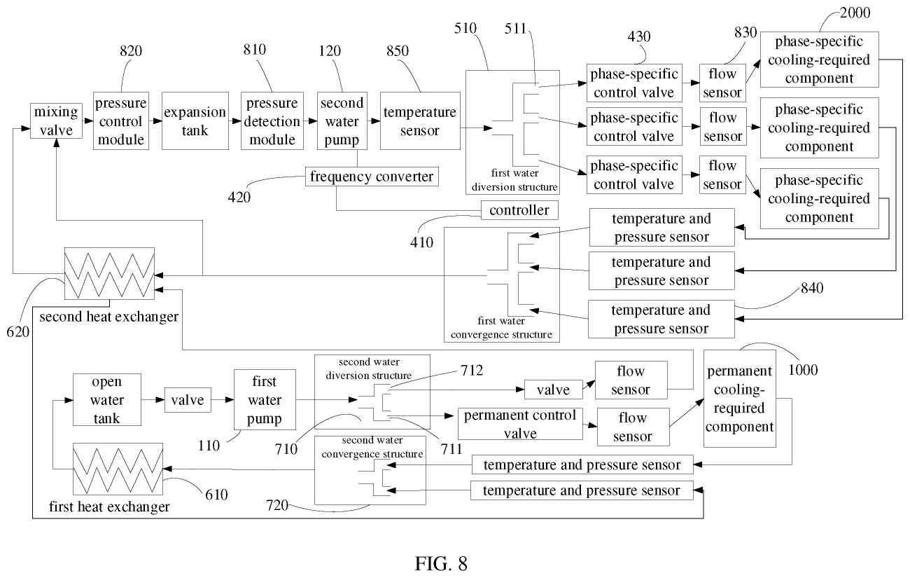

Referring to FIG. 7 and FIG. 8, in some embodiments, the cooling pipeline can include a permanent cooling pipeline 200 and a phase-specific cooling pipeline 300, and one phase-specific cooling-required component 2000 may be provided. A first water diversion structure 510 is further disposed on the cooling pipeline. The first water diversion structure 510 includes a first permanent port 512 and a first phase-specific port 511. The first permanent port 512 and the first phase-specific port 511 are connected to the permanent cooling pipeline 200 and the phase-specific cooling pipeline 300, respectively. The cooling liquid delivered by the variable frequency water pump 130 is delivered to the periphery of the permanent cooling-required component 1000 through the permanent cooling pipeline 200 via the first permanent port 512. The cooling liquid delivered by the variable frequency water pump 130 is delivered to the periphery of the phase-specific cooling-required component 2000 through the phase-specific cooling pipeline 300 via the first phase-specific port 511. As such, cooling of both the permanent cooling-required component 1000 and at least one phase-specific cooling-required component 2000, or only cooling of the permanent cooling-required component 1000, can be realized through one variable frequency water pump 130, thereby realizing on-demand cooling to reduce power consumption.

Referring to FIG. 7 and FIG. 8, in some embodiments, a plurality of phase-specific cooling-required components 2000 can be provided, and the phase-specific cooling pipeline 300 can include a plurality of first phase-specific branches 310. The first water diversion structure 510 is provided with a first permanent port 512 and a plurality of first phase-specific ports 511. The first permanent port 512 is connected to the permanent cooling pipeline 200. The plurality of first phase-specific ports 511 are connected to the plurality of first phase-specific branches 310 in a one-to-one correspondence. Phase-specific control valves 430 are respectively disposed in the first phase-specific branches 310 to independently control the cooling liquid flowing through three first phase-specific branches 310. For example, in the embodiment shown in the accompanying drawings, the number of phase-specific cooling-required components 2000 is three, and the three phase-specific cooling-required components 2000 are a gradient coil, a gradient power amplifier, and a radio frequency power amplifier, respectively. The permanent cooling-required component 1000 may be a helium compressor. Correspondingly, the number of the first phase-specific ports 511, the first phase-specific branches 310, and the phase-specific control valves 430 are all three. As such, cooling of the permanent cooling-required component 1000 and the plurality of phase-specific cooling-required components 2000, or only cooling of the permanent cooling-required component 1000, can be realized at the same time, realizing on-demand cooling and reducing power consumption.

Referring to FIG. 7 and FIG. 8, in an embodiment, the cooling device is set to a two-stage refrigeration mode. The cooling liquid delivered by the variable frequency water pump 130 is delivered to the periphery of the permanent cooling-required component 1000 through the permanent cooling pipeline 200 via the first water diversion structure 510. The cooling liquid delivered by the variable frequency water pump 130 is delivered to the periphery of the phase-specific cooling-required component 2000 through the phase-specific cooling pipeline 300 via the first water diversion structure 510. The cooling device includes two driving sources, where the variable frequency water pump 130 serves as one driving source, and an additional driving source is provided. The cooling device further includes a heat exchanger and a primary water-cooling assembly. A water inlet (hot water port) of the heat exchanger is connected to the permanent cooling pipeline 200 and the phase-specific cooling pipeline 300. A water outlet (cold water port) of the heat exchanger is connected to the variable frequency water pump 130. A primary water-cooling pump (not shown in the drawings) and a primary water-cooling pipeline (not shown in the drawings) constitute the primary water-cooling assembly. The primary water-cooling pump is configured to drive primary water in the primary water-cooling pipeline. The temperature of the primary water may be about 6 °C to 15 °C. The primary water-cooling pipeline is thermally coupled to the heat exchanger, thereby taking away the heat of the cooling liquid entering the heat exchanger through the hot water port, so that the cooled cooling liquid enters the variable frequency water pump 130 through the cold water port, and thus can be used for cooling the permanent cooling-required component 1000 and the phase-specific cooling-required component 2000. It can be understood that the cooling liquid in the cooling pipeline driven by the variable frequency water pump 130 is secondary water, and the temperature of the secondary water may be between 18 °C and 22 °C. In this case, the primary water-cooling pump needs to operate continuously. The variable frequency water pump 130 meets the demands of both the permanent cooling-required component 1000 and the phase-specific cooling-required component 2000 at the same time, and the variable frequency water pump 130 adjusts the cooling liquid flow rate and output power according to the cooling demand of the phase-specific cooling pipeline 300, that is, the permanent cooling-required component 1000 and the phase-specific cooling-required component 2000 use the same driving source to realize cooling.

In an embodiment, the permanent cooling-required component 1000 and the phase-specific cooling-required component 2000 use different driving sources, respectively. In some embodiments, the permanent cooling-required component 1000 may be a helium compressor, and the cooling device is provided with a primary water-cooling assembly. The primary water-cooling assembly includes a primary water-cooling pump (not shown in the drawings) and a primary water-cooling pipeline (not shown in the drawings). The primary water-cooling pipeline is connected to the helium compressor. The primary water-cooling pump is configured to drive primary water in the primary water-cooling pipeline. The primary water-cooling pump is configured to deliver the primary water to the helium compressor through the primary water-cooling pipeline. Cooling of the helium compressor is realized through the primary water-cooling pump and the primary water-cooling pipeline. In some embodiments, the cooling device includes a heat exchanger. A water inlet of the heat exchanger is connected to the phase-specific cooling pipeline 300 in the cooling pipeline. A water outlet of the heat exchanger is connected to the variable frequency water pump 130. The heat exchanger is thermally coupled to the primary water-cooling pipeline, thereby taking away the heat of the cooling liquid entering the heat exchanger through the water inlet, so that the cooled cooling liquid enters the variable frequency water pump 130 through the water outlet, and thus the cooled cooling liquid can be configured to cool the phase-specific cooling-required component 2000. In this case, the primary water-cooling pump needs to operate continuously. The cooling liquid in the cooling pipeline, driven by the variable frequency water pump 130, is secondary water. The variable frequency water pump 130 can be turned off when there is no cooling demand of the phase-specific cooling-required component 2000, so as to reduce the power consumption of the cooling device.

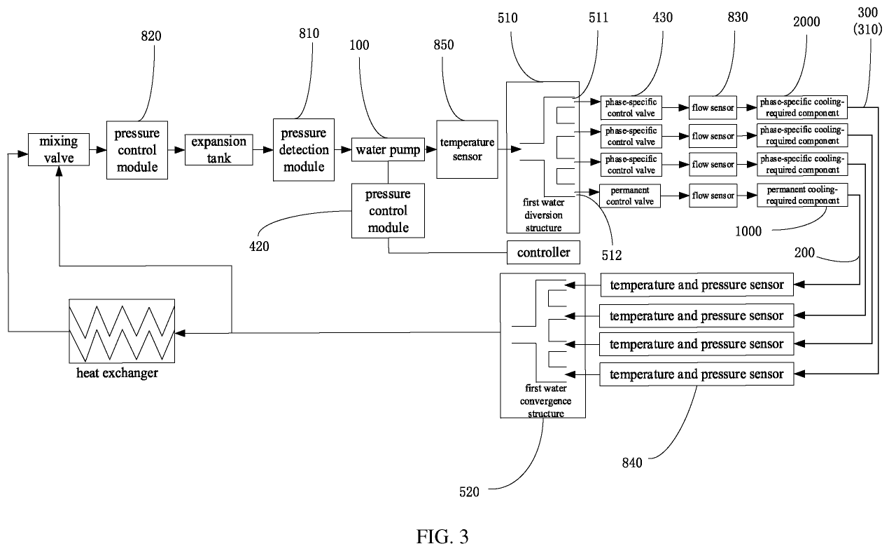

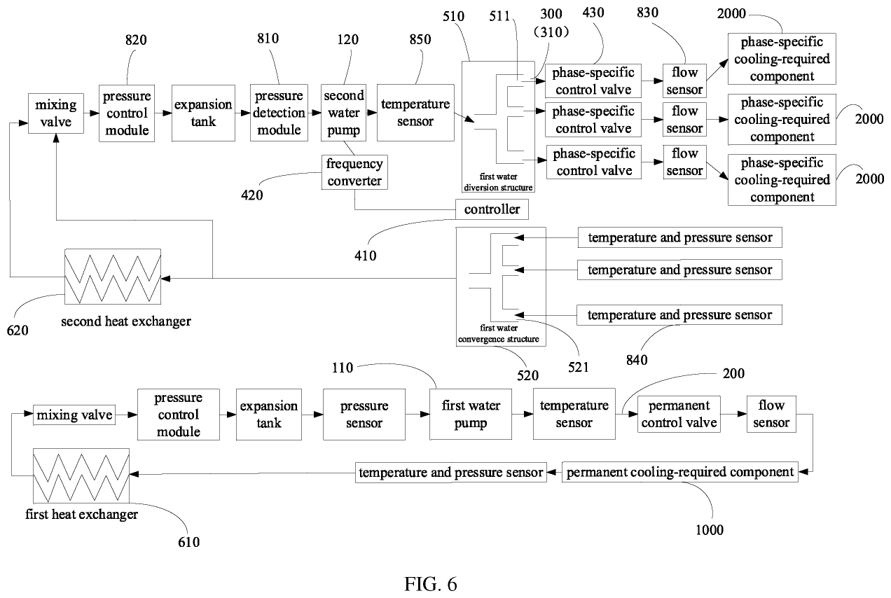

Referring to FIG. 3 and FIG. 6, in the cooling device applied to a medical imaging device provided in an embodiment of the present disclosure, the medical imaging device includes a permanent cooling-required component 1000 and at least one phase-specific cooling-required component 2000. The cooling device includes at least one water pump 100, a cooling pipeline, a controller 410, a frequency converter 420, and a phase-specific control valve 430 arranged between the water pump 100 and the phase-specific cooling-required component 2000. The water pump 100 is connected to the permanent cooling-required component 1000 and the phase-specific cooling-required component 2000 through the cooling pipeline to deliver a cooling liquid to the permanent cooling-required component 1000 and the phase-specific cooling-required component 2000. For example, the cooling pipeline includes a permanent cooling pipeline 200 and a phase-specific cooling pipeline 300. The permanent cooling pipeline 200 is connected to the permanent cooling-required component 1000, so that the cooling liquid pumped by the water pump 100 is configured to cool the permanent cooling-required component 1000. The phase-specific cooling pipeline 300 is connected to the phase-specific cooling-required component 2000, so that the cooling liquid pumped by the water pump 100 is configured to cool the phase-specific cooling-required component 2000.

The controller 410 is connected to at least one phase-specific cooling-required component 2000, and is configured to determine a state of the medical imaging device, and generate a control instruction corresponding to the state of the medical imaging device. The state of the medical imaging device is determined according to an operating state of the phase-specific cooling-required component 2000. The frequency converter 420 is connected to the controller 410. The frequency converter 420 is configured to set an operating frequency in response to the control instruction. The water pump 100 is connected to the frequency converter 420, and the operating frequency of the water pump 100 is adjusted through the frequency converter 420. According to the formula: n=60 f/p, where n is the rotation speed, f is the frequency, and p is the number of motor pole pairs, it can be known that the operating frequency of the water pump 100 is related to the rotation speed of the water pump 100. When the frequency increases, the motor rotation speed increases accordingly. When the frequency decreases, the rotation speed decreases synchronously, and the two basically show a linear relationship. By adjusting the rotation speed of the water pump 100, the cooling liquid delivered by the water pump 100 only meets the demand of the permanent cooling-required component 1000, or the cooling liquid delivered by the water pump 100 meets the demands of both the permanent cooling-required component 1000 and the phase-specific cooling-required component 2000 at the same time. The phase-specific control valve 430 adjusts the flow rate of the cooling liquid delivered to the phase-specific cooling-required component 2000 by changing the opening degree.

Taking the medical imaging device, such as a magnetic resonance device, as an example, the permanent cooling-required component 1000 is a component that requires cooling at all times, for example, a helium compressor. Regardless of whether the magnetic resonance device is scanning, the helium compressor needs to be cooled by a cooling device to maintain the superconducting low-temperature state of the superconducting magnet, otherwise the superconducting magnet will quench and damage the system. The phase-specific cooling-required component 2000, such as a gradient coil, a gradient power amplifier, a radio frequency power amplifier, etc, is a component that requires cooling in certain stages, such as scanning. The cooling device is configured to obtain the cooling demand of the phase-specific cooling-required component 2000, and then adjusts the operating frequency and rotation speed of the water pump 100, so that the cooling liquid delivered by the water pump 100 cools the permanent cooling-required component 1000, or cools both the permanent cooling-required component 1000 and the phase-specific cooling-required component 2000 at the same time.

For example, when the magnetic resonance device is scanning, the cooling demand of the phase-specific cooling-required component 2000 is relatively high, the operating frequency and rotation speed of the water pump 100 increase, correspondingly, the opening degree of the phase-specific control valve 430 increases, and the flow rate of the cooling liquid entering the phase-specific cooling-required component 2000 increases. When the magnetic resonance device is in a standby state, the cooling demand of the phase-specific cooling-required component 2000 is relatively low, the operating frequency and rotation speed of the water pump 100 can be reduced, correspondingly, the opening degree of the phase-specific control valve 430 decreases, and the flow rate of the cooling liquid entering the phase-specific cooling-required component 2000 decreases. When the magnetic resonance device is in a power-off state, the opening degree of the phase-specific control valve 430 is zero. As such, the cooling liquid will not enter the phase-specific cooling-required component 2000. As such, the cooling loss of the phase-specific cooling-required component 2000 in non-scanning states, such as a standby state and a power-off state, is reduced, so that the power consumption of the cooling device is reduced. On-demand cooling can be realized, and the cooling demands of the permanent cooling-required component 1000 and the phase-specific cooling-required component 2000 are met.

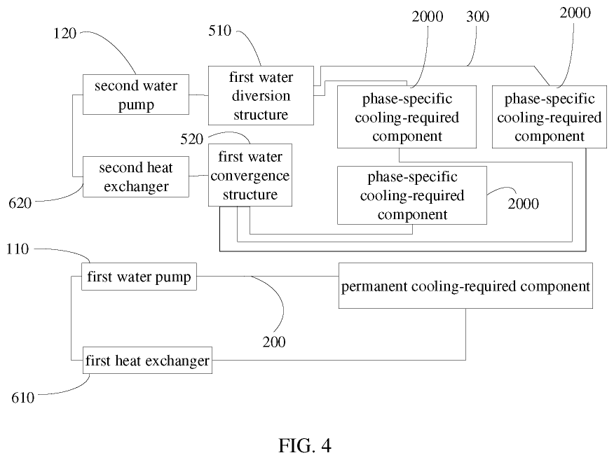

Referring to FIG. 4 to FIG. 6, in some embodiments, the cooling device includes a plurality of water pumps 100. One of the water pumps 100 is a first water pump 110, and the other of the water pumps 100 is a second water pump 120. The cooling pipeline includes a permanent cooling pipeline 200 and a phase-specific cooling pipeline 300. The permanent cooling pipeline 200 is connected to the first water pump 110 and the permanent cooling-required component 1000, so that at least part of the cooling liquid pumped by the first water pump 110 is configured to cool the permanent cooling-required component 1000. The phase-specific cooling pipeline 300 is connected to the second water pump 120 and the phase-specific cooling-required component 2000. The cooling device can adjust the operating frequency of the second water pump 120 based on the cooling demand of the phase-specific cooling-required component 2000. The second water pump 120 is in an off state when the medical imaging device is in a hibernation state or a power-off state. It can be understood that when the magnetic resonance device is in a scanning state or a standby state, the second water pump 120 is in an on state, so that at least part of the cooling liquid pumped by the second water pump 120 cools the phase-specific cooling-required component 2000.

As such, the first water pump 110 and the second water pump 120 are operated separately. When the phase-specific cooling-required component 2000 does not need heat dissipation, the system can control to turn off the second water pump 120, saving system power consumption. When the phase-specific cooling-required component 2000 needs heat dissipation, the second water pump 120 can be started to dissipate heat for the phase-specific cooling-required component 2000.

The cooling demand of the phase-specific cooling-required component 2000 is obtained, and then the operating frequency of the second water pump 120 is controlled. For example, when the medical imaging device is in the scanning state, the operating frequency of the second water pump 120 increases. When the medical imaging device is in the standby state, the heat dissipation demand of the phase-specific cooling-required component 2000 is relatively low, and the operating frequency of the second water pump 120 can be reduced. The second water pump 120 is in an off state when the medical imaging device is in a non-scanning state, such as the hibernation state or the power-off state. The cooling loss of the phase-specific cooling-required component 2000 in the non-scanning state is reduced, so that the power consumption of the cooling device is reduced. On-demand cooling can be realized, and the cooling demands of the permanent cooling-required component 1000 and the phase-specific cooling-required component 2000 are met.

In an embodiment, the medical imaging device may be a magnetic resonance device. The magnetic resonance device includes a superconducting magnet (a magnet for short), a gradient coil, and a body radio frequency coil. The superconducting magnet defines a bore. The gradient coil and the body radio frequency coil are sequentially disposed in a bore from outside to inside.

The superconducting magnet can generate a main magnetic field. After excitation. The superconducting magnet excites nuclear spins in the patient's body in a detection area. The helium compressor is a driving unit that provides refrigeration for the magnet and is configured to provide high-purity helium to the magnet. The compressor is configured to compress helium into liquid helium and delivers the liquid helium to the superconducting magnet through a helium pipe, so as to maintain the superconducting performance of the superconducting magnet by keeping the low temperature with the liquid helium.

The gradient coil assembly is located inside the magnet assembly and can generate gradient field components Gx, Gy, and Gz in different directions. The gradient field can be superimposed on the main magnetic field generated by the magnet assembly, so that the magnetic orientation of the protons of the object can be changed according to their positions in the gradient field, thereby encoding spatial information into the MR signals generated by the region of the subject to be imaged. The gradient coil assembly may include an X coil configured to generate a gradient field component Gx corresponding to the x direction, a Y coil configured to generate a gradient field component Gy corresponding to the y direction, and a Z coil configured to generate a gradient field component Gz corresponding to the z direction. The above three orthogonal gradient coils are all powered by independent current drive amplifiers.

A radio frequency power amplifier, an impedance matching network, and an impedance matching network constitute a driving system of the body radio frequency coil. The radio frequency power amplifier is configured to generate a preset radio frequency signal. The impedance matching network is configured to receive the preset radio frequency signal and transmit the preset radio frequency signal to a transmit-receive state control unit. The impedance matching network includes a matching inductor and a matching capacitor. The equivalent impedance of the matching inductor and the matching capacitor is configured to adapt to the load impedance of the body radio frequency coil to realize impedance matching. The transmit-receive state control unit is configured to transmit the preset radio frequency signal to the body radio frequency coil to generate a radio frequency field. This embodiment only takes the magnetic resonance device as an example for description, but it is not a limitation on the application environment of the cooling device of this embodiment.

Referring to FIG. 4 to FIG. 6, in an embodiment, by obtaining the operating state of the phase-specific cooling-required component 2000, the cooling demand of the phase-specific cooling-required component 2000 and the state of the medical imaging device can be determined. The state of the medical imaging device includes a power-off state, a hibernation state, a standby state, and a scanning state. The scanning state can be divided into a low-power scanning state and a high-power scanning state. For example, when the scanning power is less than 10 kW to 15 kW, the scanning power can be regarded as a low-power scanning state. When the scanning power is greater than 10 kW to 15 kW, the scanning power can be regarded as a high-power scanning state, etc. It can be understood that the division basis of the high-power scanning state and the low-power scanning state herein is only an example, and the specific division can be determined according to the medical imaging device in actual applications.

In an embodiment, the system state of the phase-specific cooling-required component 2000 can be determined according to preset time conditions. For example, from 8:00 a.m. to 12:00 p.m. and from 2:00 p.m. to 6:00 p.m., the phase-specific cooling-required component 2000 is in the scanning state. From 12:00 p.m. to 2:00 p.m., the phase-specific cooling-required component 2000 is in the standby state. From 6:00 p.m. to 8:00 a.m. the next day, the phase-specific cooling-required component 2000 is in the hibernation state.

In an embodiment, the medical imaging device includes a control system (not shown in the drawings). The time period corresponding to each operating state of the phase-specific cooling-required component 2000 is stored in the control system. The control system is configured to obtain the operating state corresponding to the phase-specific cooling-required component 2000 in the current time period, and then determines the cooling demand of the phase-specific cooling-required component 2000.

In another embodiment, the medical imaging device further includes a first detection element (not shown in the drawings). The first detection element can be independently provided or can be integrated inside the medical imaging device. The first detection element is configured to send a test signal to the control system of the medical imaging device and determines whether the medical imaging device is in the scanning state according to a test result. For example, the first detection element is configured to send a test signal to the control system of the medical imaging device. When the control system of the medical imaging device can receive the test signal, the control system outputs a feedback signal to the first detection element, indicating that the medical imaging device is in the scanning state. When no feedback signal is received, it indicates that the medical imaging device is in the non-scanning state. The first detection element detects whether the medical imaging device is in the scanning state in real time, and the operating state of the phase-specific cooling-required component 2000 can be determined according to the scanning state, ensuring the timeliness and accuracy of the switching of the cooling circuit.

In an embodiment, the first detection element may be an integrated sensor module, which has a built-in microcontroller to generate an electrical signal and transmit the electrical signal to the medical imaging device through a sensor network. The sensor module is configured to receive a confirmation signal sent by the control system of the medical imaging device, indicating the current state of the medical imaging device.

In an embodiment, the cooling device includes a first temperature detection element (not shown in the drawings) configured to obtain the temperature of the phase-specific cooling-required component 2000. The cooling demand of the phase-specific cooling-required component 2000 is determined based on the temperature information detected by the first temperature detection element. Specifically, the first temperature detection element detects the temperature of the phase-specific cooling-required component 2000, and outputs a detection result, so as to determine the cooling demand, and then determine the operating frequency of the water pump 100. In an aspect, the possibility that the phase-specific cooling-required component 2000 is not cooled in time when the temperature is too high can be avoided, ensuring the operation reliability of the power components. In another aspect, unnecessary power consumption waste caused by excessive cooling can also be prevented.

In an embodiment, the temperature detected by the first temperature detection element can be output to the control system of the medical imaging device, and the control system can determine the cooling demand of the phase-specific cooling-required component 2000 according to the temperature information. The first temperature detection element may be a temperature sensor.

Referring to FIG. 4 to FIG. 6, in an embodiment, the controller 410 is configured to obtain the cooling demand of the phase-specific cooling-required component 2000, for example, obtain the operating state or temperature of the phase-specific cooling-required component 2000 to determine the cooling demand of the phase-specific cooling-required component 2000, and control the frequency converter 420 to adjust the operating frequency of the second water pump 120 according to the cooling demand of the phase-specific cooling-required component 2000.

In an embodiment, the controller 410 is connected to the control system of the medical imaging device, obtains the operating state corresponding to the phase-specific cooling-required component 2000 in the current time period through the control system, and feeds the operating state back to the controller 410. When the phase-specific cooling-required component 2000 is in the scanning state, the phase-specific cooling-required component 2000 needs cooling, and the frequency converter 420 is controlled to operate in the high-frequency state. When the system is configured to operate in the standby state, i.e., a non-scanning state, the heat dissipation of the component is relatively low, and the frequency converter 420 is controlled to operate in the low-frequency state. After the standby state is maintained for a period of time, when the component does not operate, the phase-specific cooling-required component 2000 operates in the hibernation state. When the phase-specific cooling-required component 2000 operates in the hibernation state, the phase-specific cooling-required component 2000 does not operate, and no water cooling heat dissipation is required. The frequency converter 420 is controlled to turn off the second water pump 120, saving system power consumption.

In another embodiment, the temperature detection may also be used. The first temperature detection element detects the temperature of the phase-specific cooling-required component 2000, and feeds the temperature back to the controller 410 or the control system of the medical imaging device, and the cooling demand is determined by the controller 410 or the control system. When the temperature of the phase-specific cooling-required component 2000 is relatively high, heat dissipation needs to be increased, the operating frequency of the frequency converter 420 is increased, and the flow rate of the cooling liquid is increased. Otherwise, the operating frequency of the frequency converter 420 is reduced. The controller 410 receives the instruction control of the system, and independently performs a frequency conversion on the second water pump 120.

Referring to FIG. 4 to FIG. 6, in an embodiment, the cooling device includes a first water diversion structure 510 connected to the second water pump 120, and the first water diversion structure 510 includes a plurality of first phase-specific ports 511. The phase-specific cooling pipeline 300 includes a plurality of first phase-specific branches 310. The plurality of first phase-specific branches 310 are connected to the plurality of first phase-specific ports 511 in a one-to-one correspondence. The plurality of first phase-specific branches 310 are connected to the plurality of phase-specific cooling-required components 2000 in a one-to-one correspondence. When a plurality of phase-specific cooling-required components 2000 are provided, the cooling liquid pumped by the second water pump 120 is introduced into the plurality of first phase-specific branches 310 through the first water diversion structure 510, to dissipate heat for the phase-specific cooling-required components 2000 connected to each first phase-specific branch 310.

Referring to FIG. 4 to FIG. 6, in an embodiment, the cooling device includes a first water convergence structure 520. The first water convergence structure 520 includes a plurality of first water convergence ports 521. The plurality of first phase-specific branches 310 are connected to the plurality of first water convergence ports 521 in a one-to-one correspondence. The cooling liquid flowing through each phase-specific cooling-required component 2000 is converged through the first water convergence structure 520.

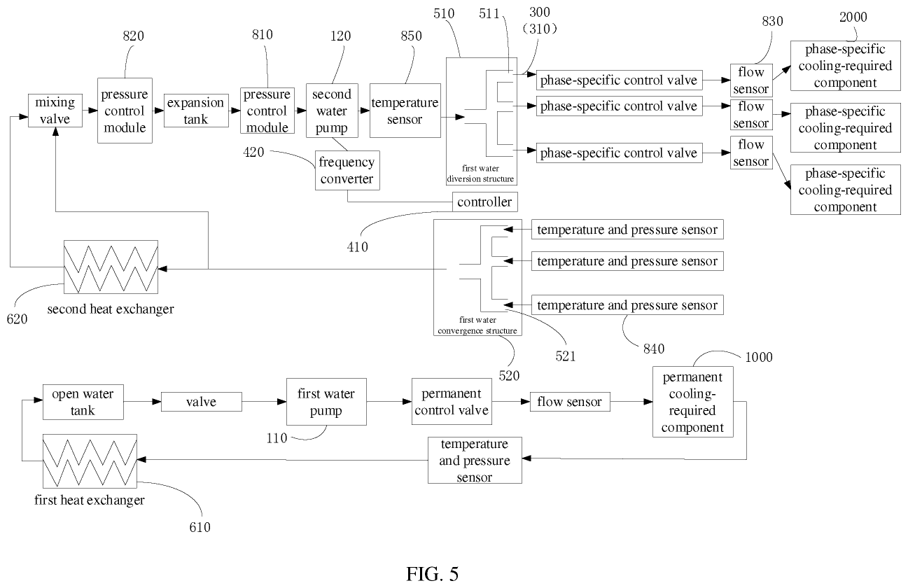

Referring to FIG. 4 and FIG. 5, in an embodiment, the cooling device includes a first heat exchanger 610. A hot water port of the first heat exchanger 610 is connected to the permanent cooling pipeline 200. A cold water port of the first heat exchanger 610 is connected to the first water pump 110, so that the cooling liquid flowing out of the permanent cooling-required component 1000 can enter the first heat exchanger 610, and perform heat exchange at the first heat exchanger 610, so that the cooling liquid with lower temperature flowing out of the first heat exchanger 610 enters the first water pump 110 again for cooling the permanent cooling-required component 1000. The cooling device includes a second heat exchanger 620. The hot water port of the second heat exchanger 620 is connected to the phase-specific cooling pipeline 300. The cold water port of the second heat exchanger 620 is connected to the second water pump 120, so that the cooling liquid flowing out of the phase-specific cooling-required component 2000 can enter the second heat exchanger 620, and perform heat exchange at the second heat exchanger 620, so that the cooling liquid with lower temperature flowing out of the second heat exchanger 620 enters the second water pump 120 again for cooling the phase-specific cooling-required component 2000. By arranging a heat exchanger in the cooling circuit, the recycling of the cooling medium can be realized, and energy waste can be reduced. At the same time, parameters such as the flow rate, temperature, or air speed of the cooling medium can also be adjusted to realize precise control of the temperature of the cooling circuit, ensuring that the system is configured to operate within the optimal operating temperature range. In an embodiment, the first heat exchanger 610 and the second heat exchanger 620 may be plate heat exchangers. Hot water and cold water are transmitted inside the plate heat exchanger. Heat is fully exchanged through a material with high thermal conductivity (such as copper) and an appropriate transmission distance (multi-layer coils). The hot water is cooled into cold water by the upper-level cooling liquid.

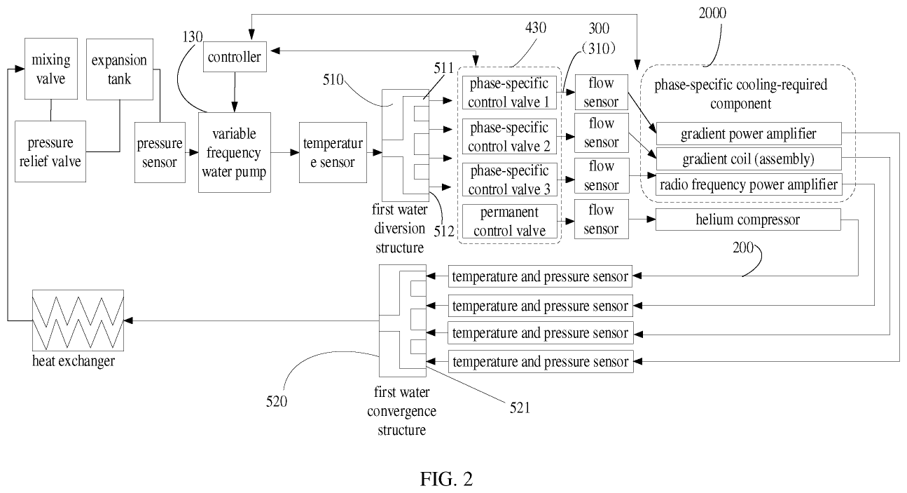

Referring to FIG. 1 and FIG. 2, in an embodiment, the cooling device includes a second water diversion structure 710 connected to the first water pump 110, and the second water diversion structure 710 includes a second permanent port 711 and a second phase-specific port 712. The second permanent port 711 is connected to the permanent cooling pipeline 200. The second phase-specific port 712 is connected to the cold water port of the second heat exchanger 620. In some embodiments, the cooling device further includes a second water convergence structure 720, and the second water convergence structure 720 includes a plurality of second water convergence ports. The plurality of second water convergence ports are connected to the permanent cooling pipeline 200 and the hot water port of the second heat exchanger 620, respectively. The cooling liquid is converged through the second water convergence structure 720 and introduced into the first heat exchanger 610.

It can be seen that in addition to providing cooling liquid to the permanent cooling-required component 1000, the first water pump 110 also provides cold water to the second heat exchanger 620 matched with the second water pump 120 at the same time, that is, serving as an upper-level chiller of the second heat exchanger 620, taking away the heat exchange amount of the second heat exchanger 620. The outlet water temperature of the first water pump 110 is lower than the inlet water temperature of the second water pump 120, that is, the first water pump 110 is a primary water chiller, for example, the cold water temperature supply range is 6 °C-15 °C, and the second water pump 120 is a secondary water chiller, for example, the water cooling temperature supply range is 18 °C-26 °C. As such, the complexity of the cooling device can be simplified. The first water pump 110 provides a branch for supplying water to the permanent cooling-required component 1000, so that the second water pump 120 independently supplies water to the phase-specific cooling-required components 2000, such as the gradient power amplifier, the radio frequency power amplifier, the gradient coil, etc., and the second water pump 120 can be controlled independently. When the phase-specific cooling-required component 2000 does not need heat dissipation, the second water pump 120 stops operating, and the first water pump 110 continues to provide cooling for the components that need cooling.

As shown in FIG. 6, in other embodiments, the permanent cooling pipeline 200 and the phase-specific cooling pipeline 300 are independent of each other, that is, the first water pump 110 and the second water pump 120 are independent of each other, and there is no connection between the two. The first water pump 110 and the second water pump 120 cool the permanent cooling-required component 1000 and the phase-specific cooling-required component 2000, respectively.

In some embodiments, the first water pump 110 that cools the permanent cooling-required component 1000 does not cool the phase-specific cooling-required component 2000, and the second water pump 120 that cools the phase-specific cooling-required component 2000 does not cool the permanent cooling-required component 1000. That is, the water pump for cooling the permanent cooling-required component is dedicated to the permanent cooling-required component, and the water pump for cooling the phase-specific cooling-required component is dedicated to the phase-specific cooling-required component.

In some embodiments, the first cooling circuit and the second cooling circuit are separate from each other. The first water pump 110 is configured to only cool the permanent cooling-required component 1000 through the permanent cooling pipeline 200, and the second water pump 120 is configured to only cool the phase-specific cooling-required component 2000 through the phase-specific cooling pipeline 300. In this case, the cooling liquid pumped by the first water pump 110 does not flow through the phase-specific cooling-required component 2000, and the cooling liquid pumped by the second water pump 120 does not flow through the permanent cooling-required component 1000.

In some other embodiments, the first cooling circuit and the second cooling circuit are not completely separate. For example, the first water pump 110 can also be used for heat exchange of the second cooling circuit. In an example, the first water pump 110 provides cold water to the second heat exchanger 620 in the second cooling circuit through the second water diversion structure 710, thereby taking away the heat of the second heat exchanger 620, so that the first water pump 110 serves as an upper-level chiller of the second heat exchanger 620. In this case, the first water pump 110 is configured to cool the permanent cooling-required component 1000 while also providing cooling capacity for the second cooling circuit.

In an embodiment, at least one of the phase-specific cooling pipeline 300 and the permanent cooling pipeline 200 is provided with a flow sensor 830. For example, in the embodiment shown in FIG. 6, both the phase-specific cooling pipeline 300 and the permanent cooling pipeline 200 are provided with flow sensors 830. A permanent control valve is disposed in the permanent cooling pipeline 200. The flow sensor 830 in the permanent cooling pipeline 200 is connected to an outlet of the permanent control valve. The flow sensor 830 of the phase-specific cooling pipeline 300 is connected to an outlet of the phase-specific control valve 430. The flow sensor 830 can continuously monitor the flow rate of the cooling liquid in the phase-specific cooling pipeline 300 and the permanent cooling pipeline 200, provide real-time data feedback, and can cooperate with the control valve on the corresponding pipeline (the phase-specific control valve 430 or the permanent control valve) to form closed-loop control. At the same time, by monitoring the flow change, problems such as pipeline blockage, pipeline leakage, or water pump 100 failure can be found in time. Further, the operating parameters of the cooling device (such as the operating frequency of the second water pump 120) can be adjusted according to flow data to achieve the optimal cooling effect and save energy. Moreover, the flow distribution on each branch can also be ensured to meet the corresponding cooling demand, avoiding local overheating or insufficient cooling.

Referring to FIG. 4 to FIG. 6, in an embodiment, the water outlets of the first water pump 110 and the second water pump 120 are each provided with a temperature sensor 850. The outlet water temperatures of the first water pump 110 and the second water pump 120 are monitored by the temperature sensors 850 to ensure cooling reliability. The first water pump 110 and the second water pump 120 are the first water pump and the second water pump, respectively. The permanent cooling pipeline 200 and the phase-specific cooling pipeline 300 are connected to the first water pump and the second water pump, respectively.

Referring to FIG. 6, in an embodiment, at least one of the phase-specific cooling pipeline 300 and the permanent cooling pipeline 200 is provided with a temperature and pressure sensor 840. Taking the phase-specific cooling pipeline 300 being provided with the temperature and pressure sensor 840 as an example, the temperature and pressure sensor 840 is disposed between the phase-specific cooling-required component 2000 and the first water convergence structure 520. Taking the permanent cooling pipeline 200 being provided with the temperature and pressure sensor as an example, the temperature and pressure sensor 840 is disposed between the permanent cooling pipeline 200 and the first heat exchanger 610. The temperature and pressure sensor 840 is configured to monitor the temperature of the cooling liquid and the pressure level in the pipeline to ensure that they are within the ideal range, preventing excessive or too low temperature and pressure from affecting the cooling effect or even damaging the equipment. At the same time, the pressure of each part is kept balanced, preventing leakage or rupture caused by uneven pressure. By configuring the flow sensor 830 and the temperature and pressure sensor 840 in the cooling pipeline, the efficient operation of the cooling device is ensured, and the service life of the medical imaging device is prolonged.

Referring to FIG. 6, in an embodiment, at least one of the phase-specific cooling pipeline 300 and the permanent cooling pipeline 200 is provided with a mixing valve. The mixing valve can dynamically adjust the proportion of cold fluid and hot fluid from different branches according to a set target temperature, to maintain the cooling liquid within a stable temperature range. Taking the phase-specific cooling pipeline 300 being provided with the mixing valve as an example, an inlet of the mixing valve is connected to the cold water port of the second heat exchanger 620, and is connected to the water outlet of the first water convergence structure 520. As such, part of the hot water flowing out of the first water convergence structure 520 can enter the mixing valve, and the cold water flowing out of the second heat exchanger 620 can also enter the mixing valve, thereby adjusting the proportion of cold fluid and hot fluid, controlling the temperature of the cooling liquid, and avoiding energy waste caused by excessive cooling or heating.

Referring to FIG. 6, in an embodiment, the permanent cooling pipeline 200 adopts closed cooling, that is, the cooling liquid does not directly contact the ambient air. In an embodiment, at least one of the permanent cooling pipeline 200 and the phase-specific cooling pipeline 300 is provided with a pressure detection module 810 and a pressure control module 820 connected to the pressure detection module 810. Taking the permanent cooling pipeline 200 being provided with the pressure control module 820 as an example, when the pressure detection module 810 detects that the pressure of the permanent cooling pipeline 200 is greater than a threshold, the pressure control module 820 is in a pressure relief state. In some embodiments, the pressure control module 820 includes a pressure relief valve, which is configured to maintain the pipeline pressure in a closed cooling device and relieve pressure when the pressure is too high. As shown in FIG. 5, in other embodiments, the permanent cooling pipeline 200 can use open cooling (i.e., the cooling medium can directly contact the ambient air for heat exchange), which is provided with an open water tank. The cooling liquid can directly contact the outside air, and an outlet of the open water tank is provided with a valve, so that the flow rate of the cooling liquid can be controlled according to the actual cooling demand.

As shown in FIG. 6, in an embodiment, at least one of the permanent cooling pipeline 200 and the phase-specific cooling pipeline 300 is provided with an expansion tank. Taking the phase-specific cooling pipeline 300 being provided with the expansion tank as an example, when the cooling device is configured to operate, the temperature of the cooling liquid rises, causing the volume of the cooling liquid to expand. When the second water pump 120 is turned off or the temperature of the cooling liquid drops, the volume of the cooling liquid shrinks. The expansion tank provides a space to accommodate these volume changes, preventing excessive or insufficient pressure in the system. By absorbing the volume changes of the cooling liquid, the expansion tank is configured to reduce the pressure impact on components such as the second water pump and prolongs their service life.

In an embodiment, taking the cooling device including the first water pump 110 and the second water pump 120 and the medical imaging device being a magnetic resonance device as an example, when the magnetic resonance device scans, the gradient power amplifier is in the scanning state, generating gradient current and gradient voltage, and generating gradient fields in different directions through the gradient coil for spatial encoding of magnetic resonance imaging. The radio frequency power amplifier is configured to generate radio frequency power to generate a radio frequency field for excitation of magnetic resonance signals. The helium compressor is configured to cool the superconducting magnet to maintain the low-temperature superconductivity of the superconducting magnet. Therefore, when the magnetic resonance device is in the scanning state, the above components are all in a high-power operating state with power generation, and require water cooling and heat dissipation. At this time, both the first water pump 110 and the second water pump 120 are controlled to keep operating to provide the heat dissipation of water circuits.

When the magnetic resonance device finishes scanning, although the gradient power amplifier and the radio frequency power amplifier have no power output, to enable the components to enter the scanning state at any time without waiting, the components are still in a strong power state, generating a certain power loss, being in a low-power operating state, and also requiring water cooling and heat dissipation. When the system is not scanning and remains in the standby state for a period of time, the system enters the hibernation state or the power-off state. Apparently, a user can also click an operation interface to make the system enter the hibernation state. In the hibernation state, the radio frequency power amplifier and the gradient power amplifier are in a strong-power shut-down mode, and no current is input to the gradient coil. The above three components have no high-power heat dissipation and do not require water cooling or heat dissipation. In this mode, the second water pump 120 can be in the off state.

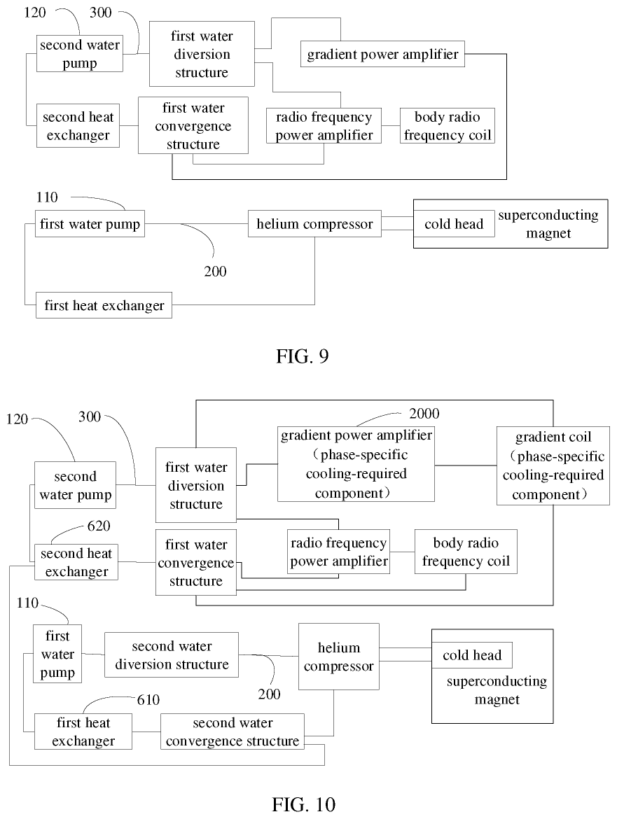

Referring to FIG. 5 or FIG. 9, in another aspect, an embodiment of the present disclosure further provides a magnetic resonance device, including a superconducting magnet, a helium compressor, a first cooling circuit, a power component, and a second cooling circuit. The superconducting magnet is configured to generate a main magnetic field. The helium compressor is configured to cool the superconducting magnet. The first cooling circuit includes a first water pump 110 and a permanent cooling pipeline 200 connected to the first water pump 110. The first cooling circuit is configured to cool the helium compressor. The power component includes a gradient power amplifier or a radio frequency power amplifier. The second cooling circuit includes a second water pump 120 and a phase-specific cooling pipeline 300 connected to the second water pump 120. The second cooling circuit is configured to cool the power component. Delivery of the cooling liquid from the second water pump 120 to the power components, such as the gradient power amplifier or the radio frequency power amplifier, is stopped when the gradient power amplifier or the radio frequency power amplifier is turned off.

Referring to FIG. 5 or FIG. 9, in some embodiments, a phase-specific control valve 430 can be disposed on the phase-specific cooling pipeline 300. The phase-specific control valve 430 adjusts the flow rate of the cooling liquid in the phase-specific cooling pipeline 300 by changing the opening degree. As such, the flow rate of the cooling liquid entering the phase-specific cooling pipeline 300 can be controlled according to the cooling demand of the power component, realizing on-demand cooling and avoiding unnecessary power waste.

Referring to FIG. 5 or FIG. 9, in some embodiments, the second water pump 120 is connected to a first water diversion structure 510. The first water diversion structure 510 includes a plurality of first phase-specific ports 511. The phase-specific cooling pipeline 300 includes a plurality of first phase-specific branches 310. The plurality of first phase-specific branches 310 are connected to the plurality of first phase-specific ports 511 in a one-to-one correspondence. The plurality of first phase-specific branches 310 are connected to the plurality of power components in a one-to-one correspondence. When there are a plurality of power components, the cooling liquid pumped by the second water pump 120 is introduced into the plurality of first phase-specific branches 310 through the first water diversion structure 510, to dissipate heat for the power components connected to the respective first phase-specific branches 310.

Referring to FIG. 5 or FIG. 9, in an embodiment, the magnetic resonance device further includes a first water convergence structure 520. The first water convergence structure 520 includes a plurality of first water convergence ports 521. The plurality of first phase-specific branches 310 are connected to the plurality of first water convergence ports 521 in a one-to-one correspondence. The cooling liquid flowing through each power component is converged through the first water convergence structure 520.

The magnetic resonance device is configured to operate the first water pump 110 and the second water pump 120 separately. When the power component does not need heat dissipation, the system can control to turn off the second water pump 120, saving system power consumption. When the power component needs heat dissipation, the second water pump 120 can be started to dissipate heat for the power component. Moreover, the operating frequency of the second water pump 120 can also be controlled according to the cooling demand of the power component. For example, when the magnetic resonance device is in the scanning state, the operating frequency of the second water pump 120 increases. When the magnetic resonance device is in the standby state, the heat dissipation demand of the power component is relatively low, and the operating frequency of the second water pump 120 can be reduced. The second water pump 120 is in the off state when the magnetic resonance device is in the non-scanning state, such as the hibernation state or the power-off state. The cooling loss of the power component in the non-scanning state is reduced, realizing on-demand cooling and reducing equipment power consumption.

Referring to FIG. 10, an embodiment of the present disclosure further provides a magnetic resonance device, including a superconducting magnet, a helium compressor, a first cooling circuit, a phase-specific cooling-required component 2000, and a second cooling circuit. The superconducting magnet is configured to generate a main magnetic field. The helium compressor is configured to cool the superconducting magnet. The first cooling circuit includes a first water pump 110, a permanent cooling pipeline 200, and a first heat exchanger 610, and the first cooling circuit is configured to cool the helium compressor. The phase-specific cooling-required component 2000 includes at least one of a gradient power amplifier, a radio frequency power amplifier, and a gradient coil. The second cooling circuit includes a second water pump 120, a phase-specific cooling pipeline 300, and a second heat exchanger 620. The second cooling circuit is configured to cool the phase-specific cooling-required component 2000. The cooling demand of the phase-specific cooling-required component 2000 is very low when the phase-specific cooling-required component 2000 is turned off or in a low power consumption state. The second water pump 120 is in the off state, and the first cooling circuit is configured to cool the second heat exchanger. As such, the helium compressor and the phase-specific cooling-required component 2000 in the low-power operating state can be cooled by the first water pump 110, realizing on-demand cooling and reducing equipment power consumption.

Referring to FIG. 8 and FIG. 10, in some embodiments, the magnetic resonance device further includes a controller 410 and a frequency converter 420 connected to the controller 410. The controller 410 is configured to obtain the cooling demand of the phase-specific cooling-required component 2000, and control the frequency converter 420 to adjust the operating frequency of the second water pump 120 according to the cooling demand of the phase-specific cooling-required component 2000. For example, the operating state or temperature of the phase-specific cooling-required component 2000 is obtained to determine the cooling demand of the phase-specific cooling-required component 2000, and the frequency converter 420 is controlled to adjust the operating frequency of the second water pump 120 according to the cooling demand of the phase-specific cooling-required component 2000, thereby adjusting the rotation speed of the second water pump 120, to adjust the flow rate of the cooling liquid pumped by the second water pump 120.

In an embodiment, a phase-specific control valve 430 connected to the controller 410 is disposed on the phase-specific cooling pipeline 300. The controller 410 is further configured to control the opening degree of the phase-specific control valve 430 according to the cooling demand of the phase-specific cooling-required component 2000. As such, the flow rate of the cooling liquid entering the phase-specific cooling pipeline 300 can be controlled according to the cooling demand of the phase-specific cooling-required component 2000, realizing on-demand cooling and avoiding unnecessary waste.

The magnetic resonance device is configured to operate the first water pump 110 and the second water pump 120 separately. When the phase-specific cooling-required component 2000 does not need heat dissipation, the system can control to turn off the second water pump 120, saving system power consumption. When the phase-specific cooling-required component 2000 needs heat dissipation, the second water pump 120 can be started to dissipate heat for the phase-specific cooling-required component 2000. Moreover, the operating frequency of the second water pump 120 can also be controlled according to the cooling demand of the phase-specific cooling-required component 2000. For example, when the magnetic resonance device is in the scanning state, the operating frequency of the second water pump 120 increases. When the magnetic resonance device is in the standby state, the heat dissipation demand of the phase-specific cooling-required component 2000 is relatively low, and the operating frequency of the second water pump 120 can be reduced. The second water pump 120 is in the off state when the magnetic resonance device is in the non-scanning state, such as the hibernation state or the power-off state. The cooling loss of the phase-specific cooling-required component 2000 in the non-scanning state is reduced, realizing on-demand cooling and reducing equipment power consumption. By providing the first heat exchanger 610 and the second heat exchanger 620 in the first cooling circuit and the second cooling circuit, respectively, the recycling of the cooling medium can be realized, and energy waste can be reduced. In addition, the first water pump 110 in the first cooling circuit can also provide cold water for the second heat exchanger 620 in the second cooling circuit, thereby taking away the heat of the second heat exchanger 620, realizing the sharing of the cooling liquid, improving the utilization of the cooling liquid, and reducing unnecessary waste.

For the above cooling device applied to the medical imaging device, taking the medical imaging device as a magnetic resonance device as an example, the phase-specific cooling-required component is a component, such as a gradient coil, a gradient power amplifier, a radio frequency power amplifier, etc, that requires cooling in certain stages, such as the scanning state. The cooling device is configured to obtain the cooling demand of the phase-specific cooling-required component, and then adjusts the rotation speed of the water pump, so that the cooling liquid delivered by the water pump is configured to cool the phase-specific cooling-required component. The cooling device cooperates with the phase-specific control valve to adjust the opening degree to adjust the flow rate of the delivered cooling liquid, meeting the actual cooling demand of the phase-specific cooling-required component. For example, when the magnetic resonance device is in the scanning state, the cooling demand of the phase-specific cooling-required component is relatively high, so the rotation speed of the water pump can be increased. Correspondingly, the opening degree of the phase-specific control valve increases, and the flow rate of the cooling liquid entering the phase-specific cooling-required component increases. When the magnetic resonance device is in the standby state, the cooling demand of the phase-specific cooling-required component is relatively low, and the rotation speed of the water pump can be reduced. Correspondingly, the opening degree of the phase-specific control valve decreases, and the flow rate of the cooling liquid entering the phase-specific cooling-required component decreases. When the magnetic resonance device is in the power-off state, the opening degree of the phase-specific control valve is zero. As such, the cooling liquid does not enter the phase-specific cooling-required component. The on-demand cooling of the phase-specific cooling components is realized, and the cooling loss of the phase-specific cooling-required component in the non-scanning state, such as the standby state and the power-off state, is reduced, so that the power consumption of the cooling device is reduced.

The technical features of the above embodiments can be combined arbitrarily. To make the description concise, all possible combinations of the technical features in the above embodiments are not described. However, as long as there is no contradiction in the combination of these technical features, it should be considered as the scope recorded in this specification. The above embodiments only represent several implementation modes of the present disclosure, and the descriptions are relatively specific and detailed, but they cannot be construed as limiting the scope of the patent application. It should be pointed out that for those of ordinary skill in the art, some modifications and improvements can be made without departing from the inventive concept of the present disclosure, which all belong to the protection scope of the present disclosure.

What is claimed is:

1. A cooling device applied to a medical imaging device, the medical imaging device comprising at least one phase-specific cooling-required component, the cooling device comprising:
a controller, connected to the at least one phase-specific cooling-required component, and configured to determine a cooling demand of the phase-specific cooling-required component and generate a control instruction according to the cooling demand of the phase-specific cooling-required component;
a variable frequency water pump, connected to the phase-specific cooling-required component through a cooling pipeline to deliver a cooling liquid to the phase-specific cooling-required component, wherein the variable frequency water pump is configured to change a rotation speed thereof in response to the control instruction to adjust a delivery volume of the cooling liquid; and
at least one phase-specific control valve, arranged between the variable frequency water pump and the phase-specific cooling-required component, wherein the phase-specific control valve is configured to adjust a flow rate of the cooling liquid delivered to the phase-specific cooling-required component by changing an opening degree of the phase-specific control valve.

2. The cooling device according to claim 1, wherein the medical imaging device further comprises a permanent cooling-required component, and the cooling pipeline comprises a permanent cooling pipeline and a phase-specific cooling pipeline;
the medical imaging device further comprises a first water diversion structure disposed on the cooling pipeline, wherein the first water diversion structure comprises a first permanent port and a first phase-specific port, and the first permanent port and the first phase-specific port are connected to the permanent cooling pipeline and the phase-specific cooling pipeline, respectively;
the variable frequency water pump is configured to deliver the cooling liquid to the periphery of the permanent cooling-required component through the permanent cooling pipeline via the first permanent port; and
the cooling liquid delivered by the variable frequency water pump is delivered to the periphery of the phase-specific cooling-required component through the phase-specific cooling pipeline via the first phase-specific port.

3. The cooling device according to claim 2, wherein the permanent cooling-required component comprises a helium compressor, and the phase-specific cooling-required component comprises a gradient coil, a gradient power amplifier, and a radio frequency power amplifier;
the phase-specific cooling pipeline comprises three first phase-specific branches, and the first water diversion structure comprises three first phase-specific ports, wherein the three first phase-specific ports are connected to the three first phase-specific branches in a one-to-one correspondence; and
the gradient coil, the gradient power amplifier, and the radio frequency power amplifier are connected to the three first phase-specific branches, respectively, and the phase-specific control valve is arranged in each of the three first phase-specific branches to independently control the cooling liquid flowing through the three first phase-specific branches.

4. The cooling device according to claim 2, wherein the cooling device further comprises:
a heat exchanger, wherein a water inlet of the heat exchanger is connected to the permanent cooling pipeline and the phase-specific cooling pipeline, and a water outlet of the heat exchanger is connected to the variable frequency water pump;
a primary water-cooling assembly, comprising a primary water-cooling pump and a primary water-cooling pipeline, wherein the primary water-cooling pipeline is thermally coupled to the heat exchanger, and the primary water-cooling pump is configured to drive primary water in the primary water-cooling pipeline;
wherein the cooling liquid in the cooling pipelines driven by the variable frequency water pump is secondary water.

5. The cooling device according to claim 1, wherein the medical imaging device further comprises a permanent cooling-required component, the permanent cooling-required component comprises a helium compressor, and the cooling device further comprises:
a primary water-cooling assembly, comprising a primary water-cooling pump and a primary water-cooling pipeline, the primary water-cooling pipeline is connected to the helium compressor, the primary water-cooling pump is configured to drive primary water in the primary water-cooling pipeline, and the primary water-cooling pump is configured to deliver the primary water to the helium compressor through the primary water-cooling pipeline;
a heat exchanger thermally coupled to the primary water-cooling pipeline, wherein a water inlet of the heat exchanger is connected to the cooling pipeline, and a water outlet of the heat exchanger is connected to the variable frequency water pump;
wherein the cooling liquid in the cooling pipeline driven by the variable frequency water pump is secondary water, and the variable frequency water pump is configured to be turned off when there is no cooling demand of the phase-specific cooling-required component.

6. A cooling device applied to a medical imaging device, the medical imaging device comprising a permanent cooling-required component and at least one phase-specific cooling-required component, the cooling device comprising:
a water pump, connected to the permanent cooling-required component and the phase-specific cooling-required component through a cooling pipeline to deliver a cooling liquid to the permanent cooling-required component and the phase-specific cooling-required component;
a controller, connected to the at least one phase-specific cooling-required component, and configured to determine a state of the medical imaging device and generate a control instruction corresponding to the state of the medical imaging device, wherein the state of the medical imaging device is determined according to an operating state of the phase-specific cooling-required component;
a frequency converter, connected to the controller, and configured to set an operating frequency in response to the control instruction, wherein the operating frequency corresponds to rotation speed adjustment of the water pump; and
at least one phase-specific control valve, arranged between the water pump and the phase-specific cooling-required component, wherein the phase-specific control valve is configured to adjust a flow rate of the cooling liquid delivered to the phase-specific cooling-required component by changing an opening degree of the phase-specific control valve.

7. The cooling device according to claim 6, wherein the state of the medical imaging device comprises one of power-off, hibernation, standby, low-power scanning, and high-power scanning.

8. The cooling device according to claim 6, wherein the cooling device comprises a plurality of water pumps, one of the water pumps serves as a first water pump, and the other of the water pumps serves as a second water pump;
the cooling pipeline comprises a permanent cooling pipeline and a phase-specific cooling pipeline;
the permanent cooling pipeline is connected to the first water pump and the permanent cooling-required component, so that at least part of the cooling liquid pumped by the first water pump is configured to cool the permanent cooling-required component; and
the phase-specific cooling pipeline is connected to the second water pump and the phase-specific cooling-required component;
wherein the second water pump is in an off state when the medical imaging device is in the state of hibernation or power-off.

9. The cooling device according to claim 8, wherein the cooling device comprises a first temperature detection element, configured to obtain a temperature of the phase-specific cooling-required component, and the cooling demand of the phase-specific cooling-required component is determined based on temperature information detected by the first temperature detection element.

10. The cooling device according to claim 9, wherein the cooling device comprises a first water diversion structure connected to the second water pump, and the first water diversion structure comprises a plurality of first phase-specific ports;
the phase-specific cooling pipeline comprises a plurality of first phase-specific branches, the plurality of first phase-specific branches are connected to the plurality of first phase-specific ports in a one-to-one correspondence, and the plurality of first phase-specific branches are connected to the plurality of phase-specific cooling-required components in a one-to-one correspondence.

11. The cooling device according to claim 10, wherein the cooling device comprises a first water convergence structure, the first water convergence structure comprises a plurality of first water convergence ports, and the plurality of first phase-specific branches are connected to the plurality of first water convergence ports in a one-to-one correspondence.

12. The cooling device according to claim 8, wherein the cooling device comprises a first heat exchanger, a hot water port of the first heat exchanger is connected to the permanent cooling pipeline, and a cold water port of the first heat exchanger is connected to the first water pump; and
the cooling device comprises a second heat exchanger, a hot water port of the second heat exchanger is connected to the phase-specific cooling pipeline, and a cold water port of the second heat exchanger is connected to the second water pump.

13. The cooling device according to claim 12, wherein the cooling device comprises a second water diversion structure connected to the first water pump, and the second water diversion structure comprises a second permanent port and a second phase-specific port, the second permanent port is connected to the permanent cooling pipeline, and the second phase-specific port is connected to the cold water port of the second heat exchanger.

14. A magnetic resonance device, comprising:
a superconducting magnet, configured to generate a main magnetic field;
a helium compressor, configured to cool the superconducting magnet;
a first cooling circuit, comprising a first water pump and a permanent cooling pipeline connected to the first water pump, wherein the first cooling circuit is configured to cool the helium compressor;
a power component, comprising a gradient power amplifier or a radio frequency power amplifier;
a second cooling circuit, comprising a second water pump and a phase-specific cooling pipeline connected to the second water pump, wherein the second cooling circuit is configured to cool the power component, and delivery of the cooling liquid from the second water pump to the gradient power amplifier or the radio frequency power amplifier is turned off when the gradient power amplifier or the radio frequency power amplifier is turned off.

15. The magnetic resonance device according to claim 14, wherein a phase-specific control valve is arranged on the phase-specific cooling pipeline, and the phase-specific control valve is configured to adjust a flow rate of the cooling liquid in the phase-specific cooling pipeline by changing an opening degree of the phase-specific control valve.

16. The magnetic resonance device according to claim 14, wherein the second water pump is connected to a first water diversion structure, and the first water diversion structure comprises a plurality of first phase-specific ports; and
the phase-specific cooling pipeline comprises a plurality of first phase-specific branches, wherein the plurality of first phase-specific branches are connected to the plurality of first phase-specific ports in a one-to-one correspondence, and the plurality of first phase-specific branches are connected to a plurality of power components in a one-to-one correspondence.

17. The magnetic resonance device according to claim 16, wherein the magnetic resonance device further comprises a first water convergence structure, the first water convergence structure comprises a plurality of first water convergence ports, and the plurality of first phase-specific branches are connected to the plurality of first water convergence ports in a one-to-one correspondence.

18. The magnetic resonance device according to claim 14, in response to the second water pump is in an off state, the first cooling circuit is configured to cool the second heat exchanger.

19. The magnetic resonance device according to claim 18, wherein the magnetic resonance device further comprises a controller and a frequency converter connected to the controller, the controller is configured to obtain a cooling demand of the power component and control the frequency converter to adjust an operating frequency of the second water pump according to the cooling demand of the power component.

20. The magnetic resonance device according to claim 19, wherein a phase-specific control valve connected to the controller is arranged on the phase-specific cooling pipeline, and the controller is further configured to control an opening degree of the phase-specific control valve according to the cooling demand of the power component.
